(19) United States
(12) Patent Application Publication
(10) Pub. No.: US 2003/0126532 A1
(43) Pub. Date: Jul. 3, 2003

(54) Integrated circuit

(76) Inventors: Martin Huch, Munchen (DE); Ernst-Josef Kock, Kirchseeon (DE); Jurgen Mammitzsch, Gauting (DE); Wolfgang Wagner, Munchen (DE); Hans Sulzer, Erding (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/330,443

(22) Filed: Dec. 27, 2002

(30) Foreign Application Priority Data
Dec. 27, 2001 (EP) 01 130 849.1

(51) Int. Cl. G01R 31/28

(52) U.S. Cl. 714/726

(57) ABSTRACT

The integrated circuit described is distinguished by the fact that flip-flops which are contained in it and which are not connected in series in normal operation of the integrated circuit can be connected in series at the instigation of the integrated circuit, and/or that flip-flops which are contained in it can be interconnected to form one or more rings. This makes it possible to reduce the outlay for carrying out the burn-in procedure.

### BACKGROUND OF THE INVENTION

### FIELD OF THE INVENTION

The present invention relates to an apparatus having an integrated circuit.

Integrated circuits have been known for many years in innumerable embodiments and require no further explanation.

A known problem of integrated circuits is that comprehensively testing them after their production is very costly.

The tests that must be carried out include, inter alia, the so-called “burn-in test”.

During the burn-in test, the integrated circuit to be tested is firstly subjected to a burn-in procedure, and then tested with regard to its proper functioning.

During the burn-in procedure, the integrated circuit is operated in such a way that as far as possible all switchable elements of the integrated circuit carry out as many switching operations as possible. For the sake of completeness, it should be noted that the burn-in procedure is preferably carried out in a chamber heated to a high temperature, and using an elevated supply voltage.

There are two possibilities for operating the integrated circuit during the burn-in procedure.

The first possibility involves a control device that is contained in the integrated circuit and that may be, by way of example, the CPU of a program-controlled unit, or a state machine of some other synchronous digital circuit, driving the individual components of the integrated circuit in such a way that as many switching operations as possible take place.

The second possibility involves the integrated circuit being put into a state in which the flip-flops of the integrated circuit are interconnected to form one or more scan chains, and fixedly prescribed data sequences or data sequences generated by a random generator being shifted through the scan chains.

The first possibility enables specific components of the integrated circuit, such as, in particular, memories contained in the integrated circuit, to be operated very well in the way that is desirable for the burn-in procedure. However, by this procedure, virtually all other components of the integrated circuit cannot be operated in the way that is desirable for the burn-in procedure, or can be operated thus only with a very high outlay.

These other components can be operated better by the second possibility in the way that is desirable for the burn-in procedure. On the other hand, through the second possibility, the memories contained in the integrated circuit cannot be operated in the way that is desirable for the burn-in procedure, or can be operated thus at best with a disproportionately high outlay.

Consequently, during the burn-in procedure, an integrated circuit to be tested is best operated successively or alternately according to the first possibility and according to the second possibility.

However, this is associated with a very high outlay. In particular, the activation of the integrated circuit according to the second possibility is relatively costly because, as is known, this requires the provision of an external test unit and a multiplicity of electrical connections between the external test unit and the integrated circuit to be tested. This configuration is problematic particularly when very many integrated circuits are to be subjected to the burn-in procedure simultaneously.

### Summary of the Invention

It is accordingly an object of the invention to provide an integrated circuit that overcomes the hereinafore-mentioned disadvantages of the heretofore-known devices of this general type and that reduces the outlay for the burn-in procedure.

With the foregoing and other objects in view, there is provided, in accordance with the invention, an integrated circuit distinguished by the fact that flip-flops that are contained in the integrated circuit and that are not connected in series in normal operation of the integrated circuit can be connected in series at the instigation of the integrated circuit. Furthermore, flip-flops that are contained in the integrated circuit can be interconnected to form one or more rings.

The need to instigate the abovementioned interconnection of the flip-flops, that is to say the interconnection of the flip-flops to form flip-flop chains or flip-flop rings, for example, from outside the integrated circuit is obviated in the case of the first-mentioned integrated circuit. In addition, a random generator can be dispensed with in the case of the second-mentioned integrated circuit.

Other features that are considered as characteristic for the invention are set forth in the appended claims.

Although the invention is illustrated and described herein as embodied in an integrated circuit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a block diagram showing an integrated circuit according to the invention and having flip-flops interconnected to form a plurality of flip-flop chains;

FIG. 2 is a block diagram showing an integrated circuit having flip-flops interconnected to form a plurality of flip-flop rings; and

FIG. 3 is a block diagram showing an integrated circuit having flip-flops interconnected to form a plurality of flip-flop chains that partly contain further elements as well.

### DESCRIPTION OF THE PREFERRED EMBODIMENTS

The integrated circuit described below is a program-controlled unit such as, for example, a microcontroller, a microprocessor, or a signal processor. However, it shall already be pointed out at this juncture that the special features—described below—of the integrated circuit considered in the present case can also be used for any other synchronous digital circuits.

The program-controlled unit considered contains a nonvolatile memory. The nonvolatile memory is preferably formed by a ROM. In the nonvolatile memory, the test programs that are to be executed during the tests to which the program-controlled unit is to be subjected after the production thereof. Among these programs there is also a program that is to be executed during the burn-in procedure; this program is referred to as burn-in program hereinafter. The determination of whether one of the test programs is executed after the activation of the program-controlled unit and which of the test programs is executed, if appropriate, can be effected from outside the program-controlled unit or by the program-controlled unit itself.

The definition of whether one of the test programs is executed after the activation of the program-controlled unit and which of the test programs is executed, if appropriate, can be effected for example by the following:

specific pins or pads of the program-controlled unit being connected to one another;

specific potentials being applied to specific pins or pads of the program-controlled unit;

fuses assigned to the different test programs being blown after the completion of the respective test;

memory cells—assigned to the different test programs of a nonvolatile memory present in the program-controlled unit being reprogrammed after the completion of the respective test;

specific registers or parts of registers of the program-controlled unit being written to from outside the program-controlled unit (for example via a serial interface such as a JTAG interface, for instance).

If the program-controlled unit is activated during the burn-in procedure, it starts to execute the burn-in program.

The burn-in program firstly drives selected or all components of the program-controlled unit in such a way that as many transistors as possible (ideally all transistors) switch as frequently as possible. In particular, it repeatedly carries out read and write accesses to the memory devices present in the program-controlled unit.

Afterward, the burn-in program instigates a series of switching operations that accomplishes the following:

flip-flops that are contained in the program-controlled unit and that are not connected in series in normal operation of the program-controlled unit are connected in series, as a result of which, one or more flip-flop chains and/or one or more flip-flop rings are formed in the program-controlled unit; and

if appropriate further operations are carried out, which will be described in more detail later.

The previously-listed switching operations can be instigated for example by the setting of one or more bits in a register. The state assumed by the switches that carry out the switching operations depend on the content of the bits. A plurality of bits are preferably used because this reduces the probability of flip-flop chains or flip-flop rings inadvertently being formed in normal operation of the program-controlled unit. It might also be provided that the relevant bit or the relevant bits can only be set if the program-controlled unit is in a specific operating mode. The operating mode is not the normal operating mode of the program-controlled unit.

In order to avoid misunderstandings, it should be noted that, of the series-connected flip-flops, the output terminal of a respective flip-flop is in each case connected to the input terminal of the flip-flop that is disposed downstream of it in series, and that the input terminal of a respective flip-flop is in each case connected to the output terminal of the flip-flop that is disposed upstream of it in series.

Furthermore, it is the case that further elements of the program-controlled unit are also connected to the output terminals of the flip-flops; this is because, for the interconnection of the flip-flops to form flip-flop chains or flip-flop rings, only different input signals than in normal operation are fed to the flip-flops, namely, instead of the input signals normally fed to the flip-flops, the output signals of the flip-flops respectively upstream of them in series. This is possible by using changeover switches, which are not shown in the Figures, are connected upstream of the input terminals of the flip-flops and, and are actuated during the formation of the flip-flop chains or flip-flop rings by the burn-in program. The abovementioned further elements to which the output terminals of the flip-flops are connected are generally for the most part logic gates, but may also include some other digital or analog circuit components such as comparators, Schmitt triggers, drivers, etc.

The flip-flops that are interconnected to form flip-flop chains or flip-flop rings preferably include every flip-flops of the program-controlled unit.

For the sake of completeness, it should be noted that the execution of the burn-in program ends with the interconnection of the flip-flops of the program-controlled unit to form flip-flop chains or flip-flop rings. The reason for this is that that component of the program-controlled unit which executes the burn-in program, that is to say the CPU of the unit, and incidentally also most of the other components of the program-controlled unit, can no longer operate as they do in normal operation of the program-controlled unit as a result of the interconnection of the flip-flops contained therein to form flip-flop chains or flip-flop rings. Consequently, from this point in time on, all operations which do not proceed automatically must be instigated from outside the program-controlled unit. The operations that do not have to be instigated from outside the program-controlled unit preferably include at least the continuous advancing—which will be described in more detail later—of the data contained in the flip-flops after the interconnection thereof to form flip-flop chains or flip-flop rings and operations which the burn-in program was still able to instigate before the interconnection of the flip-flops to form flip-flop chains or flip-flop rings.

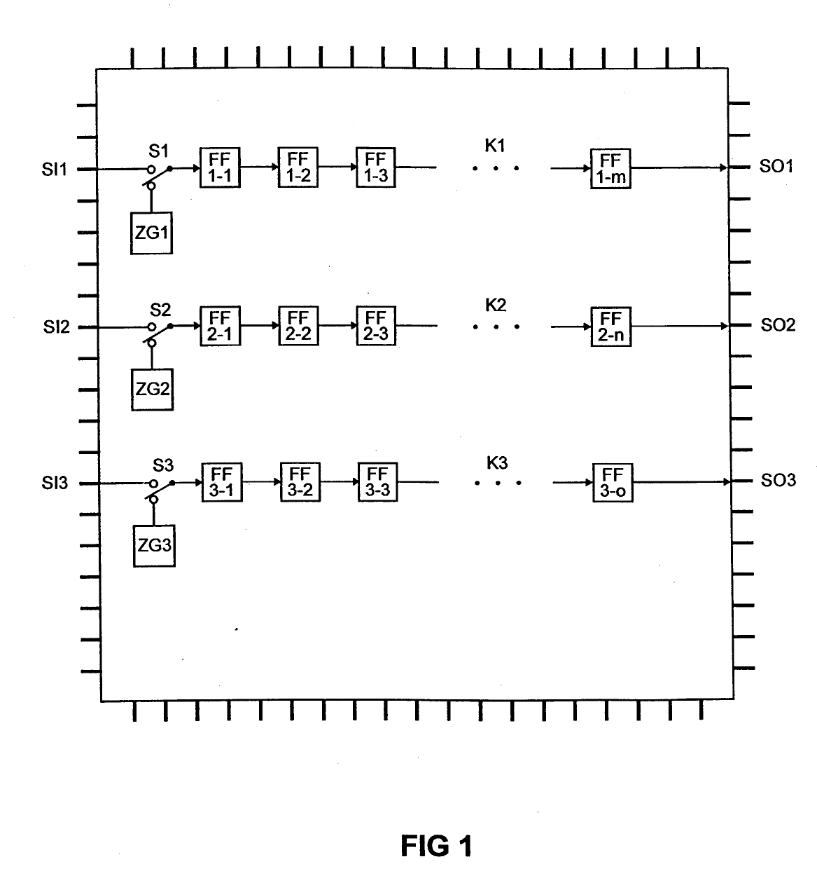

Referring now to the figures of the drawings in detail and first, particularly to FIG. 1 thereof, there is shown a program-controlled unit whose flip-flops are interconnected to form three flip-flop chains. For the sake of completeness, it shall already be pointed out at this juncture that there is no restriction to the number three; in principle, the number of flip-flop chains formed can also assume arbitrary other values.

The flip-flop chains of the program-controlled unit shown in FIG. 1 are designated by the reference symbols K1, K2, and K3, and the flip-flops of the respective flip-flop chains are designated by FF1-1 to FF1-m (flip-flop chain K1), and, respectively, FF2-1 to FF2-n (flip-flop chain K2), and, respectively, FF3-1 to FF3-o (flip-flop chain K3).

After the formation of the flip-flop chains, a random or fixedly prescribed data sequence is fed to the respective first element of the flip-flop chains. The data sequences fed to the flip-flop chains are shifted through the flip-flop chains. This is because the flip-flop chains are ultimately nothing more than shift registers: data applied to the first element of the respective flip-flop chains are advanced from flip-flop to flip-flop with the timing of the system clock used by the program-controlled unit.

As a result of the advancing of the data fed to the flip-flop chains through the flip-flop chains, switching operations take place in the flip-flops of the flip-flop chains. As a consequence of this, switching operations also take place in the other components of the program-controlled unit which are supplied with the output signals of the flip-flops or signals that depend on the output signals of the flip-flops as input signals. Overall, a very large number of switching operations take place as a result in the program-controlled unit within a very short time.

The flip-flop chains K1, K2, and K3 can, but need not, be identical to the scan chains that can be used to test the program-controlled unit before and/or after the burn-in procedure.

If the flip-flop chains K1, K2, and K3 are identical to the scan chains, the data to be fed to them can be fed via the pins or pads of the program-controlled unit to which the input terminals of the respective first flip-flop chain elements are connected, from an external test unit provided outside the program-controlled unit. The pins are designated by the reference symbols SI1, SI2, and SI3 in FIG. 1; the pins SO1, SO2, and SO3, to which the output terminals of the respective last flip-flop chain elements are connected, do not have to be connected to the external test unit because during the burn-in procedure a test of the program-controlled unit is not effected, but rather only a preparation for a test that is to be carried out afterward.

However, the data to be fed to the flip-flop chains also can be generated by one or more random generators provided in the program-controlled unit. Use is made of this possibility in the case of the program-controlled unit shown in FIG. 1. This is possible both in the case of flip-flop chains that are identical to the scan chains of the program-controlled unit and in the case of other flip-flop chains.

The program-controlled unit shown in FIG. 1 has three random generators ZG1, ZG2, and ZG3. The output terminals of these random generators can be connected via changeover switches S1, S2, and S3, respectively, to the input terminals of the respective first flip-flop chain elements. The changeover switch S1 connected upstream of the input terminal of the first flip-flop FF1-1 of the flip-flop chain K1 is able to set whether the input terminal of the flip-flop FF1-1 is connected to the pin SI1 of the program-controlled unit or to the output terminal of the random generator ZG1. The changeover switch S2 connected upstream of the input terminal of the first flip-flop FF2-1 of the flip-flop chain K2 is able to set whether the input terminal of the flip-flop FF2-1 is connected to the pin SI2 of the program-controlled unit or to the output terminal of the random generator ZG2. In addition, the changeover switch S3 connected upstream of the input terminal of the first flip-flop FF3-1 of the flip-flop chain K3 is able to set whether the input terminal of the flip-flop FF3-1 is connected to the pin SI3 of the program-controlled unit or to the output terminal of the random generator ZG3.

The changeover switches S1, S2, and S3 are changed over at the instigation of the burn-in program essentially at the same time as the formation of the flip-flop chains.

In the example considered, the random generators are formed by so-called linear feedback shift registers (LFSRs). However, differently realized random generators can also be used.

It is also not absolutely necessary for a dedicated random generator to be provided for each flip-flop chain. It might be provided, for example, that a random generator is provided only for the flip-flop chain K1 and the data fed to the other flip-flop chains are generated with a logic combination of the data generated by the random generator with temporally varying signals tapped off at specific other points of the program-controlled unit.

Irrespective of the way in which the data that are to be shifted through the flip-flop chains are generated and fed to the flip-flop chains, the same data sequences or data sequences having a complementary profile are preferably not fed to the flip-flop chains at the same time.

As has already been explained above, the flip-flops of the program-controlled unit also can be interconnected by the burn-in program to form one or more flip-flop rings.

For the sake of simplicity, each of the flip-flop rings includes one or more scan chains that are interconnected to form a ring; however, there is no restriction thereto. In principle, the flip-flop rings also can be formed entirely independently of the scan chains that are used during the testing of the program-controlled unit.

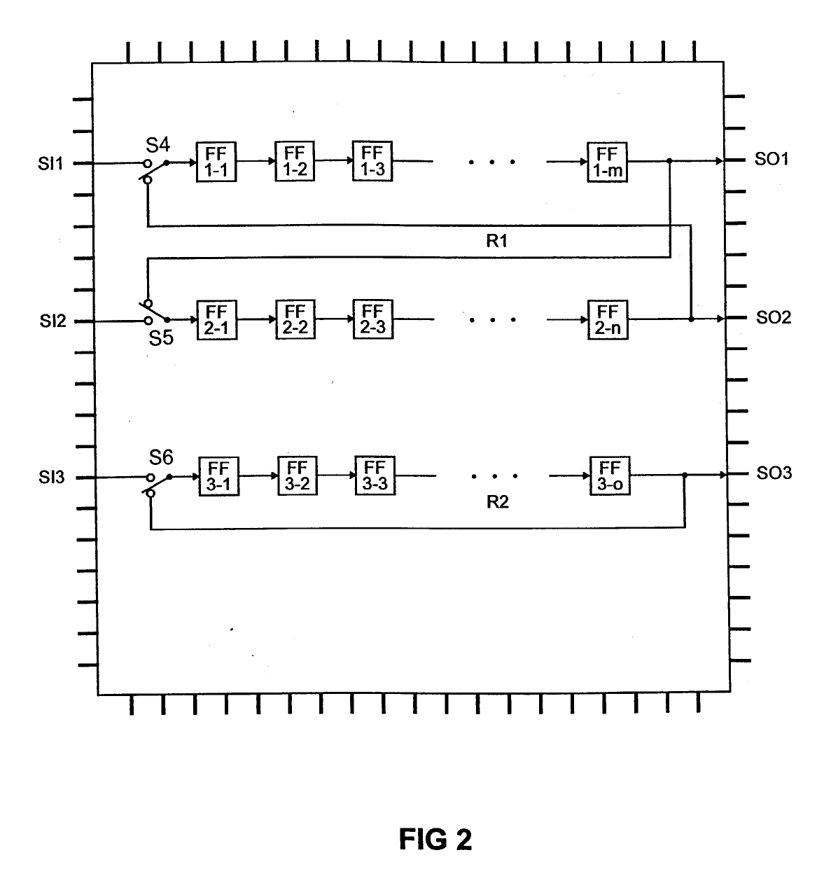

A program-controlled unit whose flip-flops are interconnected to form two flip-flop rings is illustrated in FIG. 2. For the sake of completeness, it shall already be pointed out at this juncture that there is no restriction to the number two. In principle, the number of flip-flop rings formed can also assume arbitrary other values.

The flip-flop rings of the program-controlled unit shown in FIG. 2 are designated by the reference symbols R1, and R2.

The flip-flops of the first flip-flop ring include the flip-flops FF1-1 to FF1-m of the first flip-flop chain K1 in accordance with FIG. 1 and the flip-flops FF2-1 to FF2-n of the second flip-flop chain K2 in accordance with FIG. 1, and the flip-flops of the second flip-flop ring R2 including the flip-flops FF3-1 to FF3-o of the third flip-flop chain K3 in accordance with FIG. 1.

In other words, the first flip-flop ring R1 contains the flip-flop chains K1 and K2 in accordance with FIG. 1 (the scan chains formed by the flip-flop chains K1 and K2), and the second flip-flop ring R2 contains the flip-flop chain K3 in accordance with FIG. 1 (the scan chain formed by the flip-flop chain K3). The output terminal of the last flip-flop FF1-m of the flip-flop chain K1 is connected to the input terminal of the first flip-flop FF2-1 of the flip-flop chain K2, and the output terminal of the last flip-flop FF2-n of the flip-flop chain K2 is connected to the input terminal of the first flip-flop FF1-1 of the flip-flop chain K1. The output terminal of the last flip-flop FF3-o of the flip-flop chain K3 is connected to the input terminal of the first flip-flop FF3-1 of the flip-flop chain K3.

Changeover switches S4, S5, and S6 form the connections. The changeover switches S4, S5, and S6 are connected upstream of the input terminals of the respective first flip-flops FF1-1, FF2-1, and FF3-1 of the flip-flop chains K1, K2, and K3. The changeover switch S4 can set whether the input terminal of the first flip-flop FF1-1 of the flip-flop chain K1 is connected to the pin SI1 of the program-controlled unit or to the output terminal of the flip-flop FF2-n of the flip-flop chain K2. The changeover switch S5 can set whether the input terminal of the first flip-flop FF2-1 of the flip-flop chain K2 is connected to the pin SI2 of the program-controlled unit or to the output terminal of the flip-flop FF1-m of the flip-flop chain K1. The changeover switch S6 can set whether the input terminal of the first flip-flop FF3-1 of the flip-flop chain K3 is connected to the pin SI3 of the program-controlled unit or to the output terminal of the last flip-flop FF3-o of the flip-flop chain K3.

The changeover switches S4, S5, and S6 are changed over at the instigation of the burn-in program essentially at the same time as the formation of the flip-flop rings.

After the formation of the flip-flop rings, the data stored in the flip-flops at the time of the flip-flop ring formation are advanced from flip-flop to flip-flop in the circle with the timing of the system clock used by the program-controlled unit.

As a result of the advancing of the data, switching operations take place in the flip-flops of the flip-flop rings. As a consequence of this, switching operations also take place in the other components of the program-controlled unit which are supplied with the output signals of the flip-flops or signals that depend on the output signals of the flip-flops as input signals. Overall, a very large number of switching operations take place as a result in the program-controlled unit within a very short time.

In particular when the flip-flop rings R1 and R2 contain different numbers of flip-flops, i.e. when m+n ≠o, the feeding of data generated by a random generator into the flip-flop rings can be dispensed with. This is because it takes a very long time, more precisely (m+n)*o clock cycles, until all flip-flops have the same content again, and the operations proceeding in the program-controlled unit are repeated.

Irrespective of this, data can be transferred into the flip-flop rings R1 and/or R2 and the advanced data can be altered. This can be done for example by inserting between two flip-flops one or more logic gates whose input terminals are connected to the output terminals of one or more arbitrary flip-flops (including to the output terminals of flip-flops which are part of other flip-flop rings), and/or to specific other points of the program-controlled unit at which temporally varying signals are established.

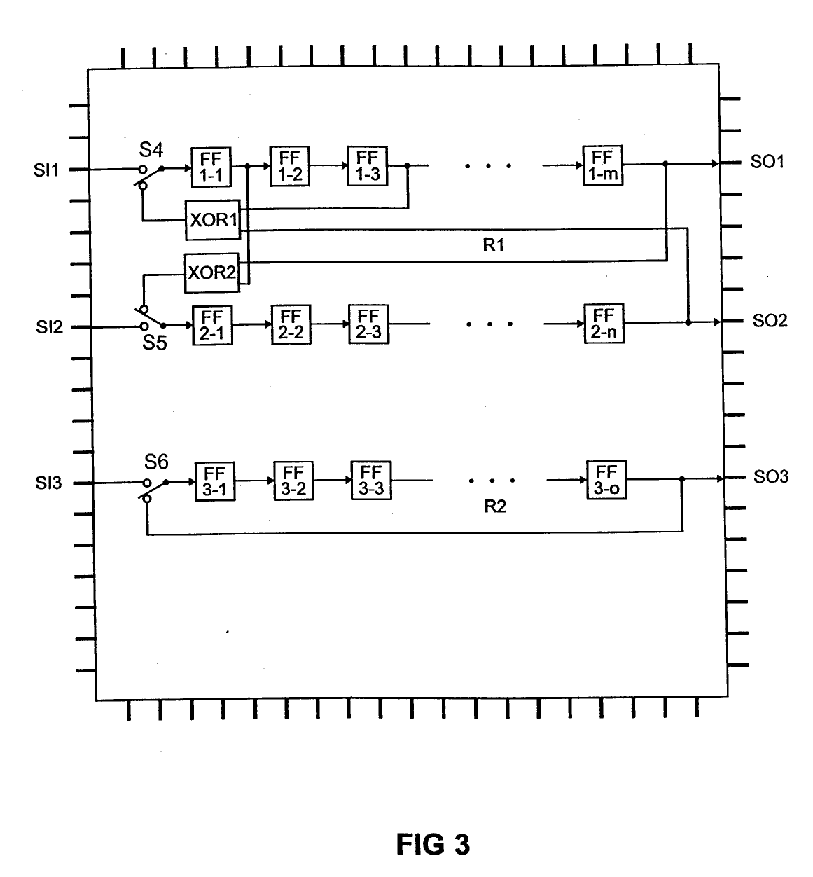

One example of this is illustrated in FIG. 3. FIG. 3 shows a program-controlled unit having flip-flops interconnected to form two flip-flop rings. Apart from the special features described below, this program-controlled unit corresponds completely to the program-controlled unit shown in FIG. 2; elements designated by the same reference symbols designate identical or mutually corresponding elements. The special features of the program-controlled unit shown in FIG. 3 are that the first flip-flop chain ring R1 contains additional elements, more precisely two EXOR gates designated by the reference symbols XOR1 and XOR2. The EXOR gate XOR1 is disposed between the last flip-flop FF2-n of the second flip-flop chain K2 and the changeover switch S4, and receiving as input signals the output signal of the flip-flop FF2-n and the output signal of the flip-flop FF1-3. The EXOR gate XOR2 is disposed between the last flip-flop FF1-m of the first flip-flop chain K1 and the changeover switch S5. The EXOR gate XOR2 receives, as input signals, the output signal of the flip-flop FF1-m and the output signal of the flip-flop FF1-1.

Through the insertion of the EXOR gates XOR1 and XOR2, the flip-flop ring R1 itself forms a random generator, more precisely itself forms an LFSR.

What is achieved by the incorporation of the EXOR gates or other logic gates into the flip-flop rings is that the data shifted through the flip-flop rings are altered in a specific manner or randomly.

EXOR gates or other logic gates can also be incorporated into the flip-flop chains in accordance with FIG. 1 in order to alter the data shifted through the flip-flop chains in a specific manner or randomly.

The data shifted through the flip-flop chains or the flip-flop rings can also be altered by carrying out a so-called capture cycle instead of a shift cycle (preferably at irregular time intervals). In the case of such a capture cycle, the series circuit of flip-flops is resolved for one or more clock cycles, as a result of which the flip-flops are again operated in the way that is the case during normal operation of the program-controlled unit. The flip-flop chains or flip-flop rings are resolved by a changeover of the changeover switches (not shown in the Figs.) already mentioned above, which are connected upstream of the input terminals of the flip-flops, and which were changed over by the burn-in program for the purpose of forming the flip-flop chains or the flip-flop rings. The data accepted from the flip-flops after the resolution of the flip-flop chains or flip-flop rings are not, or at any rate for the most part not, the data output by other flip-flops, but rather data generated by other components of the program-controlled unit. If the flip-flops are subsequently connected together again to form flip-flop chains or flip-flop rings, then the flip-flops thereof have a different content than was the case before the resolution of the flip-flop chains or flip-flop rings. Consequently, the advancing of the data stored in the flip-flops, which recommences after the re-establishment of the flip-flop chains or flip-flop rings, triggers, in the program-controlled unit, different operations than was the case beforehand. The insertion of such a capture cycle can be effected for individual, a plurality or all of the flip-flop chains or flip-flop rings.

The data shifted through the flip-flop chains or the flip-flop rings can also be altered by resetting parts of the program-controlled unit (preferably at irregular time intervals). As a result, the flip-flops of the respectively reset part of the program-controlled unit, to be precise only these, can be allocated a different value.

The data shifted through the flip-flop chains or the flip-flop rings also can be altered by the burn-in program that interconnects the flip-flops to form flip-flop chains or flip-flop rings ensuring that the flip-flops do not always have the same contents at the point in time at which they are interconnected to form flip-flop chains or flip-flop rings. This can be realized for example by ensuring that the burn-in program does not always proceed in the same way, but rather executes the operations that are to be executed in a different order, and/or alternately does not execute specific operations, and/or writes to specific or all registers at different points in time and/or with different data. What can be achieved thereby is that the program-controlled unit is in different states in each case at the points in time at which the burn-in program interconnects the flip-flops to form flip-flop chains or flip-flop rings, and, consequently, the flip-flops also have other contents in each case.

The situation where the burn-in program does not always proceed in the same way can be achieved for example by the burn-in program storing, before the interconnection of the flip-flops to form flip-flop chains or flip-flop rings, data that are not erased by a resetting of the program-controlled unit and/or by a switching-off of the program-controlled unit, and by the sequence of the burn-in program being made dependent on the data the next time the program is started.

A certain time after the formation of the flip-flop chains or flip-flop rings, the latter are resolved again, and the burn-in program is started again. The operations described above are repeated in this case.

The stimulation of the integrated circuit by the burn-in program and the stimulation of the integrated circuit by the advancing of data within the flip-flop chains or flip-flop rings are preferably executed alternately without a break throughout the burn-in procedure.

As has already been mentioned in the introduction, the integrated circuit need not be a program-controlled unit. If the integrated circuit is not a program-controlled unit, the functions which, in the example described above, are performed by the CPU and the burn-in program executed on the latter can be undertaken by a different control device, such as a state machine, for example.

Irrespective of this, the integrated circuit described may also prove to be advantageous if the formation of the flip-flop chains or flip-flop rings is not instigated by an internal control device such as a CPU or a state machine, but rather from outside the integrated circuit.

The integrated circuit described makes it possible, independently of the details of the practical realization, to reduce the outlay for carrying out the burn-in procedure.

We claim:

1. An integrated circuit, comprising a plurality of flip-flops not being connected in series in a normal operation and being connectable in series upon instigation of the integrated circuit.

2. The integrated circuit according to claim 1, wherein said flip-flops are interconnected upon said instigation to form at least one flip-flop chain.

3. The integrated circuit according to claim 2, wherein said flip-flop chain includes a scan chain for testing the integrated circuit.

4. The integrated circuit according to claim 2, wherein:
said flip-flops form a plurality of flip-flop chains; and
said plurality of flip-flop chains at least partly include mutually different numbers of flip-flops.

5. The integrated circuit according to claim 4, further comprising elements; said flip-flops being interconnected to form flip-flop chains during a burn-in procedure, said burn-in procedure causing as many of said elements as possible to switch as often as possible.

6. The integrated circuit according to claim 4, further comprising a control device instigating said flip-flops to interconnect to form said flip-flop chains.

7. The integrated circuit according to claim 6, further comprising components; said control device causing as many switching operations as possible in at least a selected portion of said components before interconnecting said flip-flops to form said flip-flop chains.

8. The integrated circuit according to claim 7, wherein said control device causes as many switching operations as possible in all of said components before interconnecting said flip-flops to form said flip-flop chains.

9. The integrated circuit according to claim 2, wherein:
after interconnecting said flip-flops to form said flip-flop chain, each flip-flop in said flip-flop chain has an upstream side and a downstream side; and
each of said flip-flops forwards data stored respectively therein to said downstream side and simultaneously accepts data fed respectively thereto from said upstream side.

10. The integrated circuit according to claim 9, wherein each of said flip-flops accepts and forwards the data upon receiving a clock signal.

11. The integrated circuit according to claim 2, further comprising a random generator generating and feeding data into said flip-flop chain.

12. The integrated circuit according to claim 2, wherein said flip-flop chain at least partly contain a logic gate disposed between two of said flip-flops, one of said two flip-flops being downstream of said logic gate; said logic gate subjecting signals to a logic combination to form a result and forwarding said result of said logic combination to said flip-flop disposed downstream said logic gate.

13. The integrated circuit according to claim 2, wherein said flip-flop chain is temporarily resolved at least partly at certain time intervals.

14. The integrated circuit according to claim 2, further comprising parts being resetable at certain time intervals after interconnecting said flip-flops to form said flip-flop chain.

15. The integrated circuit according to claim 13, wherein said time intervals are irregular time intervals.

16. The integrated circuit according to claim 14, wherein said time intervals are irregular time intervals.

17. The integrated circuit according to claim 2, wherein said flip flops interconnect to form said flip-flop chain after a varying start conditions, said start conditions being a function of variables selected from the group consisting of order, type, and extent.

18. The integrated circuit according to claim 6, wherein said control device is a state machine.

19. The integrated circuit according to claim 1, wherein said flip-flops are interconnected upon said instigation to form a flip-flop ring.

20. The integrated circuit according to claim 19, wherein said flip-flop ring includes a scan ring for testing the integrated circuit.

21. The integrated circuit according to claim 19, wherein:
said flip-flops form a plurality of flip-flop rings; and
said plurality of flip-flop rings at least partly include different numbers of flip-flops.

22. The integrated circuit according to claim 21, further comprising elements; said flip-flops are interconnected to form flip-flop rings during a burn-in procedure, said burn-in procedure causing as many of said elements as possible to switch as often as possible.

23. The integrated circuit according to claim 21, further comprising a control device instigating said flip-flops to interconnect to form said flip-flop rings.

24. The integrated circuit according to claim 23, further comprising components; said control device causing as many switching operations as possible in at least a selected portion of said components before interconnecting said flip-flops to form said flip-flop rings.

25. The integrated circuit according to claim 24, wherein said control device causes as many switching operations as possible in all of said components before interconnecting said flip-flops to form said flip-flop ring.

26. The integrated circuit according to claim 19, wherein:
after interconnecting said flip-flops to form said flip-flop ring, each flip-flop in said flip-flop ring has an upstream side and a downstream side; and
each of said flip-flops forwards data stored respectively therein to said downstream side and simultaneously accepts data fed respectively thereto from said upstream side.

27. The integrated circuit according to claim 26, wherein each of said flip-flops accepts and forwards the data upon receiving a clock signal.

28. The integrated circuit according to claim 19, further comprising a random generator generating and feeding data into said flip-flop ring.

29. The integrated circuit according to claim 19, wherein said flip-flop ring at least partly contain a logic gate disposed between two of said flip-flops, one of said two flip-flops being downstream of said logic gate; said logic gate subjecting signals to a logic combination to form a result and forwarding said result of said logic combination to said flip-flop disposed downstream said logic gate.

30. The integrated circuit according to claim 19, wherein said flip-flop ring is temporarily resolved at least partly at certain time intervals.

31. The integrated circuit according to claim 19, further comprising parts being resetable at certain time intervals after interconnecting said flip-flops to form said flip-flop ring.

32. The integrated circuit according to claim 30, wherein said time intervals are irregular time intervals.

33. The integrated circuit according to claim 31, wherein said time intervals are irregular time intervals.

34. The integrated circuit according to claim 19, wherein said flip flops interconnect to form said flip-flop ring after a varying start conditions, said start conditions being a function of variables selected from the group consisting of order, type, and extent.

35. The integrated circuit according to claim 23, wherein said control device is a state device.

36. An integrated circuit, comprising flip-flops interconnected to form a flip-flop ring.

37. The integrated circuit according to claim 36, wherein said flip-flop ring includes a scan ring for testing the integrated circuit.

38. The integrated circuit according to claim 36, wherein:
said flip-flops form a plurality of flip-flop rings; and
said plurality of flip-flop rings at least partly include different numbers of flip-flops.

39. The integrated circuit according to claim 38, further comprising elements; said flip-flops are interconnected to form flip-flop rings during a burn-in procedure, said burn-in procedure causing as many of said elements as possible to switch as often as possible.

40. The integrated circuit according to claim 38, further comprising a control device instigating said flip-flops to interconnect to form said flip-flop rings.

41. The integrated circuit according to claim 40, further comprising components; said control device causing as many switching operations as possible in at least a selected portion of said components before interconnecting said flip-flops to form said flip-flop rings.

42. The integrated circuit according to claim 41, wherein said control device causes as many switching operations as possible in all of said components before interconnecting said flip-flops to form said flip-flop rings.

43. The integrated circuit according to claim 36, wherein:
after interconnecting said flip-flops to form said flip-flop ring, each flip-flop in said flip-flop ring has an upstream side and a downstream side; and
each of said flip-flops forwards data stored respectively therein to said downstream side and simultaneously accepts data fed respectively thereto from said upstream side.

44. The integrated circuit according to claim 43, wherein each of said flip-flops accepts and forwards the data upon receiving a clock signal.

45. The integrated circuit according to claim 36, further comprising a random generator generating and feeding data into said flip-flop ring.

46. The integrated circuit according to claim 36, wherein said flip-flop ring at least partly contain a logic gate disposed between two of said flip-flops, one of said two flip-flops being downstream of said logic gate; said logic gate subjecting signals to a logic combination to form a result and forwarding said result of said logic combination to said flip-flop disposed downstream said logic gate.

47. The integrated circuit according to claim 36, wherein said flip-flop ring is temporarily resolved at least partly at certain time intervals.

48. The integrated circuit according to claim 36, further comprising parts being resetable at certain time intervals after interconnecting said flip-flops to form said flip-flop ring.

49. The integrated circuit according to claim 47, wherein said time intervals are irregular time intervals.

50. The integrated circuit according to claim 48, wherein said time intervals are irregular time intervals.

51. The integrated circuit according to claim 36, wherein said flip flops interconnect to form said flip-flop chain ring after a varying start conditions, said start conditions being a function of variables selected from the group consisting of order, type, and extent.

52. The integrated circuit according to claim 40, wherein said control device is a state machine.

53. A synchronous digital circuit, comprising flip-flops not being connected in series in a normal operation and being connectable in series upon instigation.

54. A synchronous digital circuit, comprising flip-flops interconnected to form a ring.

55. A program-controlled unit, comprising:
flip-flops not being connected in series in a normal operation and being connectable in series upon instigation to form a plurality of flip-flop chains, said plurality of flip-flop chains at least partly including different numbers of flip-flops; and
a CPU instigating said flip-flops to interconnect to form said flip-flop chains.

56. A program-controlled unit, further comprising:
flip-flops not being connected in series in a normal operation and being connectable in series upon instigation to form a plurality of flip-flop rings, said plurality of flip-flop rings at least partly including different numbers of flip-flops; and
a CPU instigating said flip-flops to interconnect to form said flip-flop rings.

57. A program-controlled unit, comprising:
flip-flops interconnected to form a plurality of flip-flop rings, said plurality of flip-flop rings at least partly including different numbers of flip-flops; and
a CPU instigating said flip-flops to interconnect to form said flip-flop rings.
